(19) United States
(12) Patent Application Publication
(10) Pub. No.: US 2024/0355699 A1
(43) Pub. Date: Oct. 24, 2024

(54) SEMICONDUCTOR DEVICE THERMAL MANAGEMENT MODULE AND MANUFACTURING METHOD THEREOF

(71) Applicant: CHUNG-ANG UNIVERSITY INDUSTRY ACADEMIC COOPERATION FOUNDATION, Seoul (KR)

(72) Inventors: Hyoung Soon LEE, Seongnam-si (KR); Dae Young KONG, Incheon (KR)

(21) Appl. No.: 18/137,187

(22) Filed: Apr. 20, 2023

(51) Int. Cl. H01L 23/367; H01L 21/48

(52) U.S. Cl. CPC H01L 23/367; H01L 21/4882

(57) ABSTRACT

A semiconductor device thermal management module includes a thermal diffusion plate stacked on a semiconductor device for thermal diffusion of the semiconductor device and a heat spreader provided on the thermal diffusion plate, molded by a three-dimensional (3D) printing method, and having a channel through which a cooling fluid flows.

### TECHNICAL FIELD

The present disclosure relates to a semiconductor device thermal management module and a manufacturing method thereof, and more particularly, to a semiconductor device thermal management module with improved structure and process to improve heat dissipation efficiency of a high-heat semiconductor device such as a power semiconductor, a laser, and a radar, and a manufacturing method thereof.

### BACKGROUND ART

In general, a passive cooling method using a heat pipe or a vapor chamber, which is used for thermal management of electronic devices, deteriorates performance seriously at high heat of 100W/cm2 or more. However, most power semiconductors operate at a heat flux much higher than the high heat, there is a disadvantage in that the power semiconductors are underutilized.

Therefore, most power semiconductors operating at high heat flux have a structure in which a heat sink 502 for implementing an indirect cooling thermal management module is disposed on a semiconductor chip 501, as well shown in FIG. 1. According to this related art, there is a problem in that the use of a thermal interfacial material (TIM) 503 for attaching the heat sink 502 to the semiconductor chip 501 causes a rapid increase in total thermal resistance.

### DISCLOSURE

### Technical Problem

The present disclosure is directed to providing a semiconductor device thermal management module capable of increasing the manufacturing efficiency of a product by improving the thermal management efficiency of a power semiconductor device without using thermal interracial materials (TIM) and forming a channel through which cooling fluid flows by 3D printing, and a manufacturing method thereof.

### Technical Solution

In one aspect of the present disclosure, there is provided a semiconductor device thermal management module including a thermal diffusion plate stacked on a semiconductor device for thermal diffusion of the semiconductor device and a heat spreader provided on the thermal diffusion plate, molded by a three-dimensional (3D) printing method, and having a channel through which a cooling fluid flows.

The heat spreader includes a first spreader layer having a channel of a relatively small hydraulic diameter, and a second channel disposed on the upper side of the first spreader layer and having a second channel of a larger hydraulic diameter than that of the first channel, the second channel communicating with the first channel.

The semiconductor device thermal management module further includes a manifold disposed on an upper side of the heat spreader to introduce the cooling fluid into the channel, and having a flow path capable of communicating with the channel of the heat spreader, wherein an inlet line and a discharge line, for the cooling fluid, forming the flow path are partitioned from each other.

In another aspect of the present disclosure, there is provided a method of manufacturing a semiconductor device thermal management module including stacking a thermal diffusion plate on a semiconductor device for a thermal diffusion of the semiconductor device and forming a heat spreader having a channel through which a cooling fluid flows on the thermal diffusion plate by a 3D printing method.

The thermal diffusion plate and the heat spreader are integrally formed of the same material by the 3D printing method.

### Advantageous Effects

Unlike the related art that uses a thermal interfacial material (TIM) for thermal management of a semiconductor device, the semiconductor device thermal management module according to the present disclosure having the configuration described above is configured to directly heat the semiconductor device in the convection method by the cooling fluid through the thermal diffusion plate and the channel of the heat spreader, thereby further improving the cooling efficiency of a high-performance power semiconductor owing to a reduction in total thermal resistance due to the removal of the TIM, direct cooling through the channel, and an increase in the heat transfer area through the channel.

In addition, the semiconductor device thermal management module according to the present disclosure includes the heat spreader including the channel by the 3D printing method using a material having excellent thermal conductivity, thereby smoothly customizing and manufacturing various structures of the channel according to the performance specifications required for each product using desired materials at desired locations.

### DESCRIPTION OF DRAWINGS

FIG. 1 is a diagram illustrating a problem of a semiconductor device thermal management module according to the related art.

FIG. 2 is a cross-sectional view of a semiconductor device thermal management module according to an embodiment of the present disclosure.

FIG. 3 is a perspective view illustrating the arrangement and coupling relationship between a channel of a heat spreader and a manifold employed in an embodiment of the present disclosure.

FIG. 4 is a plan view illustrating the configuration shown in FIG. 3.

FIG. 5 is a side view illustrating the configuration shown in FIG. 3.

FIG. 6 is a cross-sectional view of a heat spreader employed in a semiconductor device thermal management module according to another embodiment of the present disclosure.

FIG. 7 is a block diagram illustrating a method of manufacturing a semiconductor device thermal management module according to an embodiment of the present disclosure.

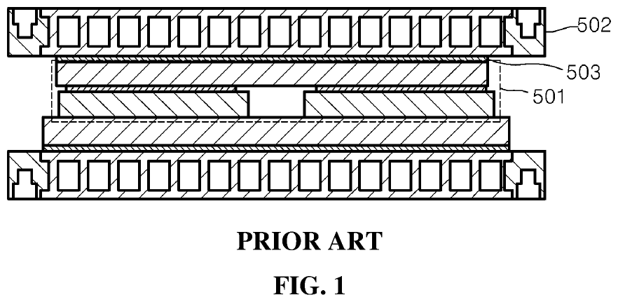

### BEST MODE

In order to clarify the understanding of the present disclosure in the following description, descriptions of well-known technology of the features of the present disclosure will be omitted. The following embodiments are detailed descriptions to help the understanding of the present disclosure, and do not to limit the scope of the present disclosure. Accordingly, equivalent inventions performing the same functions as those of the present disclosure will also fall within the scope of the present disclosure.

In addition, in the following description, the same reference numeral mean the same configuration, and unnecessary redundant descriptions and descriptions of well-known technologies will be omitted. In addition, the description of each embodiment of the present disclosure that overlaps with the description of the technology that is the background of the invention will also be omitted.

Hereinafter, a semiconductor device thermal management module device according to an embodiment of the present disclosure will be described in detail with reference to the accompanying drawings.

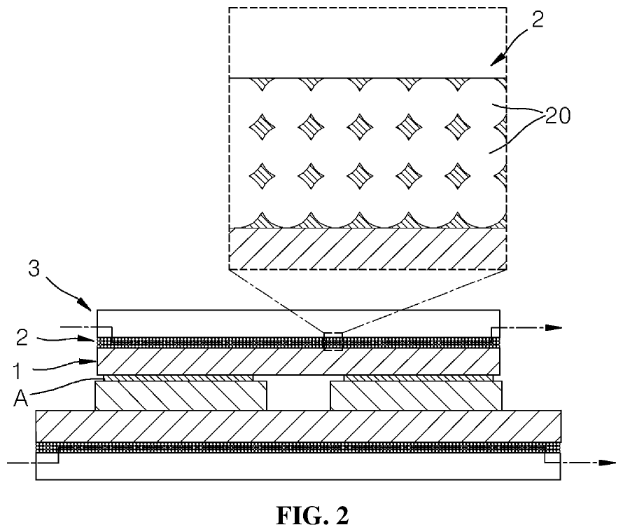

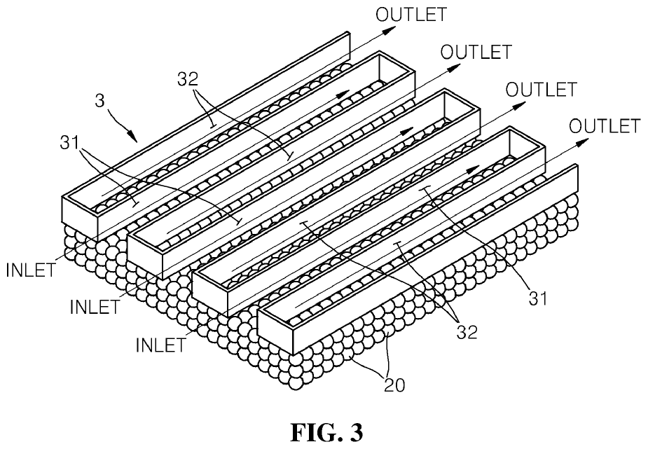

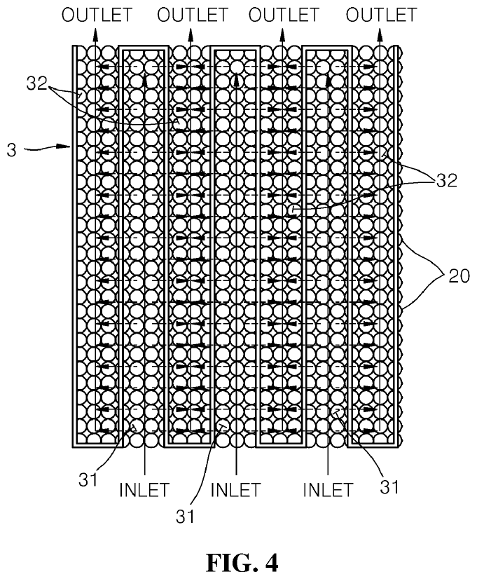

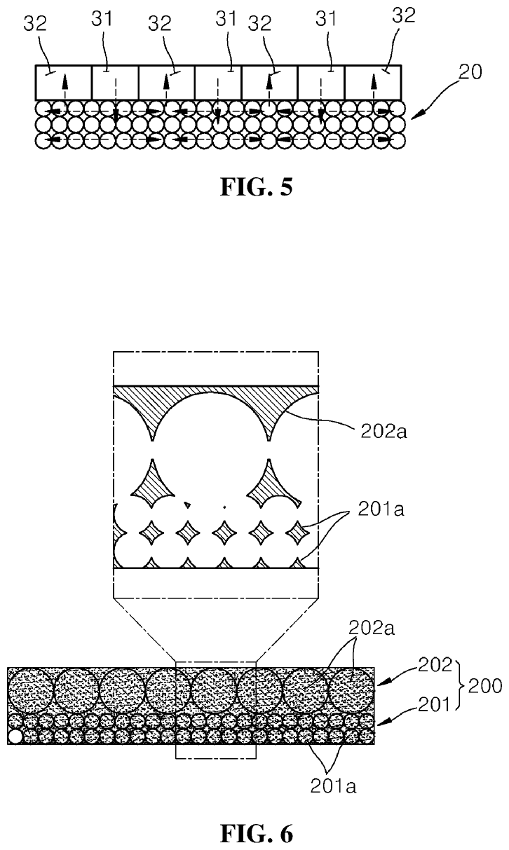

FIG. 2 is a cross-sectional view of a semiconductor device thermal management module according to an embodiment of the present disclosure. FIG. 3 is a perspective view illustrating a process of forming a channel of a heat spreader employed in an embodiment of the present disclosure. FIG. 4 is a perspective view illustrating the arrangement and coupling relationship between a channel of a heat spreader and a manifold employed in an embodiment of the present disclosure. FIG. 5 is a plan view illustrating the configuration shown in FIG. 4. FIG. 6 is a side view illustrating the configuration shown in FIG. 4.

As shown in FIG. 2, the semiconductor device thermal management module according to an embodiment of the present disclosure reduces the total thermal resistance by removing a thermal interfacial material (TIM) used for thermal management of a power semiconductor and increases a convective thermal resistance by using ac channel 20 through which a cooling fluid flows, and includes a thermal diffusion plate 1 and a heat spreader 2. The channel 20 may have a general channel shape, but has preferably a porous shape to increase a contact area with the cooling fluid.

The thermal diffusion plate 1 is stacked on a semiconductor device A for thermal diffusion of the semiconductor device A, is formed of a material having high thermal conductivity such as gold, copper, aluminum, or diamond, and is preferably formed in a flat plate shape so that heat may be dispersed and diffused through a wide surface.

The heat spreader 2 is provided on the thermal diffusion plate 1, is molded by a 3D printing method, and includes the channel 20 through which the cooling fluid flows. The channel 20 may include flow paths formed of a plurality of pores arranged to communicate with each other in a three-dimensional (3D) space.

Unlike the related art that uses the TIM for thermal management of the semiconductor device A, the semiconductor device thermal management module according to an embodiment of the present disclosure having such a configuration is configured to directly heat the semiconductor device A in the convection method by the cooling fluid through the thermal diffusion plate 1 and the channel 20 of the heat spreader 2, thereby further improving the cooling efficiency of a high-performance power semiconductor owing to a reduction in total thermal resistance due to the removal of the TIM, direct cooling through the channel 20, and an increase in the heat transfer area through the channel 20.

In addition, the semiconductor device thermal management module according to the present disclosure includes the heat spreader 2 having the channel 20 by the 3D printing method using a material having excellent thermal conductivity, thereby smoothly customizing and manufacturing various structures of the channel 20 according to the performance specifications required for each product using desired materials at desired locations.

Meanwhile, the thermal diffusion plate and the heat spreader are individually manufactured and then coupled to each other so that the heath spreader may be provided on the thermal diffusion plate, but are preferably integrally formed on a substrate of a semiconductor device or an external housing by the 3D printing method using the same or different materials so as to further improve manufacturing efficiency.

As well shown in FIGS. 3 to 5, the present disclosure preferably further includes a manifold 3 disposed on the upper side of the heat spreader 2 to introduce the cooling fluid into the channel 20. The manifold 3 has a flow path capable of communicating with the channel 20 of the heat spreader 2, and the flow path has an inlet line 31 and a discharge line 32, for the cooling fluid, partitioned from each other.

The semiconductor device thermal management module according to an embodiment of the present disclosure having such a configuration is configured to disperse and inject the cooling fluid on a wide surface area from the upper side to the lower side through the manifold 3 disposed on the upper side of the heat spreader 2, as well shown in FIG. 5, thereby having the advantage of obtaining a high convective heat transfer effect by jet impinging without ending in local cooling of the related art.

In particular, each inlet line 31 of the manifold 3 employed in the present embodiment has a structure in which an entrance is opened, an exit is closed, and a part between the entrance and the exit is formed long in an axial direction crossing the channel 20, and the discharge line 32 is disposed between adjacent elements, as well shown in FIGS. 3 and 4.

In addition, opposite to the adjacent inlet line 31, each discharge line 32 of the manifold 3, has a structure in which a part corresponding to the entrance of the inlet line 31 is closed and a part corresponding to the exit thereof is opened.

In the present embodiment having such a configuration, the inflow and discharge of the cooling fluid is possible due to the structure of the manifold 3 itself without any other additional structure, thereby deriving an advantage capable of contributing to the simplification and miniaturization of a semiconductor packaging structure by forming a flow path of the cooling fluid even with a simple configuration, and an advantage capable of improving the cooling efficiency of the semiconductor device A by evenly dispersing the cooling fluid on a wide area and introducing the cooling fluid into the channel 20 of the heat spreader 2.

Meanwhile, FIG. 6 is a cross-sectional view of a heat spreader employed in a semiconductor device thermal management module according to another embodiment of the present disclosure.

As shown in this figure, the heat spreader 200 employed in the present embodiment includes a first spreader layer 201 having a first channel 201a of a relatively small hydraulic diameter, and a second spreader layer 202 disposed on the upper side of the first spreader layer 201 and having a second channel 202a of a larger hydraulic diameter than that of the first channel 201a while communicating with the first channel 201a.

In the present embodiment having such a configuration, start of boiling may be smoothly performed through the first channel 201a of the relatively small hydraulic diameter, and an increase in the critical heat flux may be promoted through the second channel 202a of the relatively large hydraulic diameter, and thus, there is an advantage capable of maximizing improvement of the cooling efficiency through the formation of a hierarchical structure of channels.

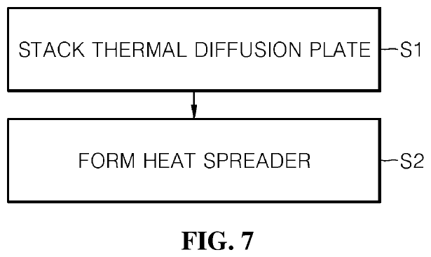

Hereinafter, a method of manufacturing a semiconductor device thermal management module according to an embodiment of the present disclosure is described in detail with reference to FIG. 7.

A method of manufacturing the semiconductor device thermal management module according to the present embodiment includes step S1 of stacking a thermal diffusion plate and step S2 of forming a heat spreader.

In the step S1 of stacking the thermal diffusion plate, the thermal diffusion plate is stacked on a semiconductor device for thermal diffusion of the semiconductor device, and in step S2 of forming the heat spreader, the heat spreader including a channel through which a cooling fluid flows is formed by a 3D printing method on the thermal diffusion plate.

In the method of manufacturing the semiconductor device thermal management module according to the present embodiment having such a configuration, unlike the related art in which a TIM is interposed for bonding between a thermal diffusion plate and a cooler for the thermal management of the semiconductor device, the heat spreader including the channel is formed on the thermal diffusion plate stacked on the semiconductor device, thereby reducing the manufacturing cost by improving the efficiency of a manufacturing process and further improving the cooling efficiency of a high-performance power semiconductor by directly cooling the semiconductor device by a convection method using the cooling fluid through the channel of the heat spreader.

Further, in the method of manufacturing the semiconductor device thermal management module according to the present embodiment, the heat spreader including the channel is formed by a 3D printing method using a material having excellent thermal conductivity, thereby smoothly customizing and manufacturing various shapes or structures of the channel 20 according to the performance specifications required for each product using desired materials at desired locations.

Meanwhile, the thermal diffusion plate and the heat spreader are individually manufactured and then coupled to each other so that the heath spreader may be provided on the thermal diffusion plate, but are preferably integrally formed by the 3D printing method using the same or different materials so as to further improve manufacturing efficiency.

In addition, in the step of forming the heat spreader, a channel having a single shape may be formed, a process of forming a first spreader layer having a first channel of a relatively small hydraulic diameter on the heat diffusion plate may be performed, and then, a process of forming, on the first spreader layer, a second spreader layer having a second channel of a larger hydraulic diameter than that of the first channel while communicating with the first channel may be performed. Here, the channel may be manufactured in various shapes by 3D printing, but may also be formed in a porous shape to secure a larger contact area with the cooling fluid.

Although various embodiments of the present disclosure have been described above, the present embodiment and the drawings attached to the present specification merely clearly present a part of the technical idea included in the present disclosure, and it will be obvious that all modifications and specific embodiments that can be easily inferred by those skilled in the art within the scope of the technical idea included in the specification and drawings of the present disclosure are included in the scope of the present disclosure.

### EXPLANATION OF REFERENCE NUMERALS

1: thermal diffusion plate
2: heat spreader
20: channel
3: manifold
31: inflow line
32: discharge line
A: semiconductor device

What is claimed is:

1. A semiconductor device thermal management module comprising:
a thermal diffusion plate stacked on a semiconductor device for thermal diffusion of the semiconductor device; and
a heat spreader provided on the thermal diffusion plate, molded by a three-dimensional (3D) printing method, and having a channel through which a cooling fluid flows.

2. The semiconductor device thermal management module of claim 1, wherein the heat spreader includes a first spreader layer having a channel of a relatively small hydraulic diameter, and a second channel disposed on an upper side of the first spreader layer and having a second channel of a larger hydraulic diameter than that of the first channel, the second channel communicating with the first channel.

3. The semiconductor device thermal management module of claim 1, further comprising a manifold disposed on an upper side of the heat spreader to introduce the cooling fluid into the channel, and having a flow path capable of communicating with the channel of the heat spreader, wherein an inlet line and a discharge line, for the cooling fluid, forming the flow path are partitioned from each other.

4. A method of manufacturing a semiconductor device thermal management module, the method comprising:
stacking a thermal diffusion plate on a semiconductor device for a thermal diffusion of the semiconductor device; and
forming a heat spreader having a channel through which a cooling fluid flows on the thermal diffusion plate by a three-dimensional (3D) printing method.

5. The method of claim 4, wherein the thermal diffusion plate and the heat spreader are integrally formed of the same material by the 3D printing method.
